(19) United States
(12) Patent Application Publication
(10) Pub. No.: US 2023/0197500 A1
(43) Pub. Date: Jun. 22, 2023

(54) WAFER PLACEMENT TABLE

(71) Applicant: NGK Insulators, Ltd., Nagoya-City (JP)

(72) Inventors: Seiya INOUE, Handa-City (JP); Hiroshi TAKEBAYASHI, Handa-City (JP); Tatsuya KUNO, Nagoya-City (JP)

(73) Assignee: NGK Insulators, Ltd., Nagoya-City (JP)

(21) Appl. No.: 18/168,032

(22) Filed: Feb. 13, 2023

Related U.S. Application Data
(63) Continuation of application No. PCT/JP2022/025141, filed on Jun. 23, 2022.

(30) Foreign Application Priority Data
Sep. 9, 2021 (JP) 2021-146681

(51) Int. Cl. H01L 21/687; H01L 23/373

(52) U.S. Cl. CPC H01L 21/68721; H01L 23/3731; H01L 23/3736

(57) ABSTRACT

A wafer placement table includes a ceramic substrate having a wafer placement surface on an upper surface thereof and containing an electrode therein, a cooling substrate made of a metal-ceramic composite and having a cooling medium passage therein, and a metal joining layer configured to join a lower surface of the ceramic substrate to an upper surface of the cooling substrate. A thickness of a lower part of the cooling substrate below the cooling medium passage is greater than or equal to 13 mm, or greater than or equal to 43% of an overall thickness of the cooling substrate.

### BACKGROUND OF THE INVENTION

### 1. Field of the Invention

The present invention relates to a wafer placement table.

### 2. Description of the Related Art

Wafer placement tables have been known in which a ceramic substrate, such as an alumina substrate, with an electrostatic attracting electrode buried therein, is joined to a cooling substrate made of metal, such as aluminum, by a resin layer interposed between the ceramic substrate and the cooling substrate (see, e.g., Patent Literature 1). In such a wafer placement table, the resin layer can reduce the influence of a difference in thermal expansion between the ceramic substrate and the cooling substrate. Wafer placement tables of another type have also been known in which, instead of a resin layer, a metal joining layer is used to join a ceramic substrate to a cooling substrate having a cooling medium passage therein (see, e.g., Patent Literatures 2 and 3). The metal joining layer has a higher thermal conductivity than a resin layer, and thus can provide a heat removing capability required when a wafer is treated with high-power plasma. However, since the metal joining layer has a greater Young’s modulus and lower stress relaxation properties than a resin layer, it can barely reduce the influence of a difference in thermal expansion between the ceramic substrate and the cooling substrate. In Patent Literatures 2 and 3, therefore, a metal matrix composite (MMC) is used to make the cooling substrate, because a difference in thermal expansion coefficient between the MMC and the ceramic substrate is small.

### CITATION LIST

### Patent Literature

PTL 1: Japanese Unexamined Patent Application Publication No. H04-287344
PTL 2: Japanese Patent No. 5666748
PTL 3: Japanese Patent No. 5666749

### SUMMARY OF THE INVENTION

The MMC is not ductile, unlike metals. Therefore, if a significant temperature difference develops in the vertical direction in an upper part of the cooling substrate above the cooling medium passage, the resulting stress may damage the upper part of the cooling substrate.

The present invention has been made to solve the problem described above. A primary object of the present invention is to prevent damage caused by stress in a wafer placement table in which a ceramic substrate and a cooling substrate are joined by a metal joining layer.

[1] A wafer placement table according to the present invention includes a ceramic substrate having a wafer placement surface on an upper surface thereof and containing an electrode therein, a cooling substrate made of a metal-ceramic composite and having a cooling medium passage formed therein, and a metal joining layer configured to join a lower surface of the ceramic substrate to an upper surface of the cooling substrate. A thickness of a lower part of the cooling substrate below the cooling medium passage is greater than or equal to 13 mm, or greater than or equal to 43% of an overall thickness of the cooling substrate.

In the wafer placement table described above, the thickness of the lower part of the cooling substrate below the cooling medium passage is greater than or equal to 13 mm, or greater than or equal to 43% of the overall thickness of the cooling substrate. Accordingly, the thickness of the upper part of the cooling substrate above the cooling medium passage is relatively small. In the upper part of the cooling substrate above the cooling medium passage, therefore, it is less likely that a significant temperature difference in the vertical direction will develop and lead to the occurrence of stress. The upper part of the cooling substrate above the cooling medium passage can thus be prevented from being damaged by the stress.

Although this specification may use such terms as upper and lower, right and left, and front and back to describe the present invention, these terms are simply used to refer to relative positional relations. If the wafer placement table is changed in orientation, “upper and lower” may be changed to “right and left”, and vice versa. Such variations are also included in the technical scope of the present invention.

[2] In the wafer placement table (or in the wafer placement table described in [1]), the thickness of the lower part of the cooling substrate below the cooling medium passage is preferably greater than or equal to 15 mm, or greater than or equal to 49% of the overall thickness of the cooling substrate. This further reduces the thickness of the upper part of the cooling substrate above the cooling medium passage in relative terms, and makes it easier to prevent the upper part of the cooling substrate above the cooling medium passage from being damaged by stress.

[3] In the wafer placement table (or in the wafer placement table described in [1] or [2]), a thickness of an upper part of the cooling substrate above the cooling medium passage is preferably less than or equal to 5 mm. This can enhance the effect of the present invention.

[4] A wafer placement table according to another aspect of the present invention includes a ceramic substrate having a wafer placement surface on an upper surface thereof and containing an electrode therein, a cooling substrate made of a metal-ceramic composite and having a cooling medium passage formed therein, and a metal joining layer configured to join a lower surface of the ceramic substrate to an upper surface of the cooling substrate. A thickness of an upper part of the cooling substrate above the cooling medium passage is less than or equal to 5 mm.

In the wafer placement table described above, the thickness of the upper part of the cooling substrate above the cooling medium passage is small. In the upper part of the cooling substrate above the cooling medium passage, therefore, it is less likely that a significant temperature difference in the vertical direction will develop and lead to the occurrence of stress. The upper part of the cooling substrate above the cooling medium passage can thus be prevented from being damaged by the stress.

[5] In the wafer placement table (or in the wafer placement table described in [3] or [4]), the thickness of the upper part of the cooling substrate above the cooling medium passage may be less than or equal to 3 mm. This can enhance the effect of the present invention.

[6] In the wafer placement table (or in the wafer placement table described in any one of [1] to [5]), the cooling substrate may have, on a lower side thereof, a flange portion configured to clamp the wafer placement table. It is preferable that a width of the flange portion be greater than or equal to 3 mm, or that an outside diameter of the flange portion be greater than or equal to 101.8% of an outside diameter of the ceramic substrate. This can reduce the risk of warpage of the wafer placement table caused by clamping the flange portion of the wafer placement table, reduce the risk of damage to the product, and improve thermal uniformity.

[7] In the wafer placement table (or in the wafer placement table described in [6]), it is more preferable that the width of the flange portion be greater than or equal to 10 mm, or that the outside diameter of the flange portion be greater than or equal to 106% of the outside diameter of the ceramic substrate. This can further reduce the risk of warpage, further reduce the risk of damage to the product, and further improve thermal uniformity.

[8] In the wafer placement table (or in the wafer placement table described in any one of [1] to [7]), upper corners of the cooling medium passage may be rounded in cross section. This can prevent the occurrence of cracks originating from the upper corners of the cooling medium passage in cross section.

[9] In the wafer placement table (or in the wafer placement table described in any one of [1] to [8]), the ceramic substrate may be an alumina substrate, and an absolute difference in linear thermal expansion coefficient at 40° C. to 570° C. between the metal-ceramic composite and alumina may be less than or equal to 1 × 10⁻⁶/K. Examples of the metal-ceramic composite include AlSiC and SiSiCTi.

### BRIEF DESCRIPTION OF THE DRAWINGS

FIG. 1 is a vertical cross-sectional view of a wafer placement table 10 installed in a chamber 94.

FIG. 2 is a plan view of the wafer placement table 10.

FIG. 3 is an explanatory diagram showing symbols representing the dimensions of the wafer placement table 10.

FIGS. 4A to 4G illustrate processes of manufacturing the wafer placement table 10.

FIG. 5 is a vertical cross-sectional view of another embodiment of the wafer placement table 10.

### DETAILED DESCRIPTION OF THE INVENTION

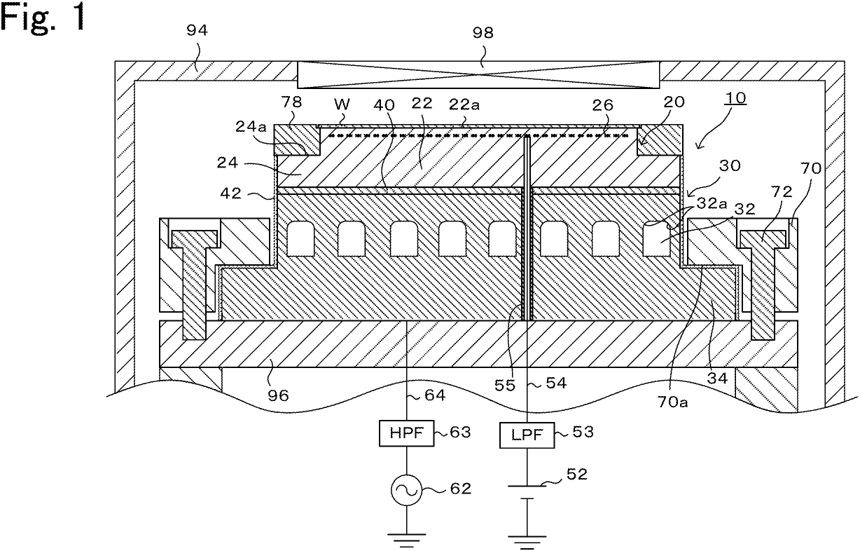

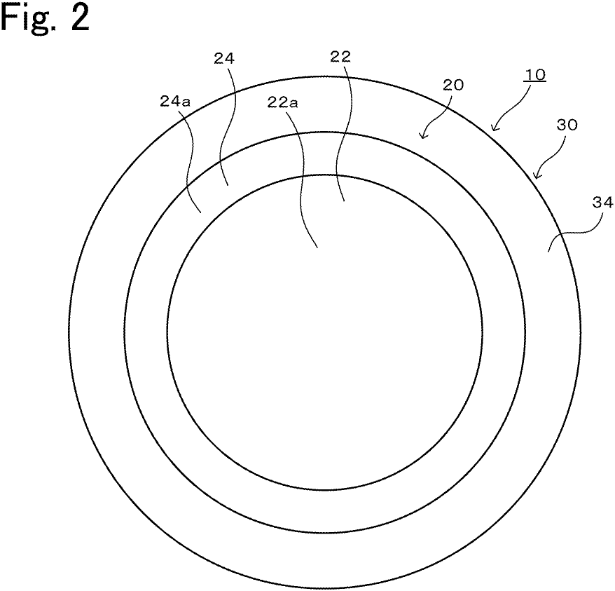

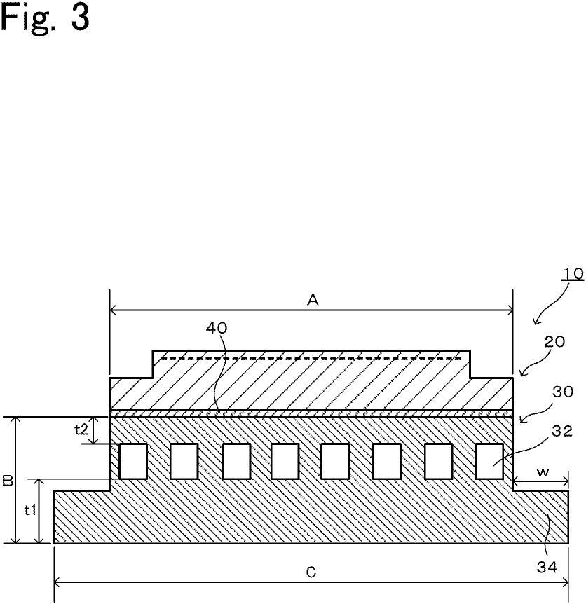

Preferred embodiments of the present invention will now be described with reference to the drawings. FIG. 1 is a vertical cross-sectional view of a wafer placement table 10 installed in a chamber 94 (i.e., a cross-sectional view taken along a plane containing a central axis of the wafer placement table 10). FIG. 2 is a plan view of the wafer placement table 10. FIG. 3 is an explanatory diagram showing symbols representing the dimensions of the wafer placement table 10. Note that when a numerical range is expressed as “(numerical value) to (numerical value)” in this specification, the range includes the numerical values before and after “to” as lower and upper limits, respectively.

The wafer placement table 10 is used to perform CVD, etching, or the like on a wafer W by using plasma, and is fixed to a mounting plate 96 provided inside a semiconductor process chamber 94. The wafer placement table 10 includes a ceramic base 20, a cooling base 30, and a metal bonding layer 40.

The ceramic base 20 includes an outer peripheral part 24 having an annular focus ring placement surface 24a, on the outer peripheral side of a central part 22 having a circular wafer placement surface 22a. Hereinafter, a focus ring may be abbreviated as “FR”. A wafer W is placed on the wafer placement surface 22a, and a focus ring 78 is placed on the FR placement surface 24a. The ceramic base 20 is made of a ceramic material, typically, alumina, aluminum nitride, or the like. The FR placement surface 24a is lower in level than the wafer placement surface 22a.

The central portion 22 of the ceramic substrate 20 contains therein a wafer attracting electrode 26 disposed adjacent to the wafer placement surface 22a. The wafer attracting electrode 26 is made of a material containing, for example, W, Mo, WC, or MoC. The wafer attracting electrode 26 is a disc-shaped or mesh-type monopolar electrostatic attracting electrode. Of layers of the ceramic substrate 20, a layer above the wafer attracting electrode 26 serves as a dielectric layer. The wafer attracting electrode 26 is connected to a wafer attracting direct-current power supply 52 by a feed terminal 54 therebetween. The feed terminal 54 passes through an insulating pipe 55 disposed in a through hole vertically penetrating the cooling substrate 30 and the metal joining layer 40, and extends from the lower surface of the ceramic substrate 20 to reach the wafer attracting electrode 26. The wafer attracting direct-current power supply 52 and the wafer attracting electrode 26 are provided with a low-pass filter (LPF) 53 therebetween.

The cooling substrate 30 is a disc member. The cooling substrate 30 is preferably made of a metal-ceramic composite. Examples of the metal-ceramic composite include a metal matrix composite (MMC) and a ceramic matrix composite (CMC). The cooling substrate 30 has therein a cooling medium passage 32 in which a cooling medium can circulate. The cooling medium passage 32 is connected to a cooling medium supply path and a cooling medium discharge path (not shown). A cooling medium discharged through the cooling medium discharge path is temperature-adjusted and returned to the cooling medium supply path. The cooling medium passing through the cooling medium passage 32 is preferably a liquid and is preferably an electrically insulating liquid. Examples of the electrically insulating liquid include a fluorinated inert liquid. Upper corners 32a of the cooling medium passage 32 are rounded in cross section. For example, the radius of curvature of the rounded portions is preferably 0.5 mm to 2 mm. An absolute difference in linear thermal expansion coefficient at 40° C. to 570° C. between a composite used in the cooling substrate 30 and a ceramic material used in the ceramic substrate 20 is preferably less than or equal to 1 × 10⁻⁶/K, more preferably less than or equal to 0.5 × 10⁻⁶/K, and still more preferably less than or equal to 0.2 × 10⁻⁶/K. Examples of the metal-ceramic composite include a material composed of Si, SiC, and Ti, a SiC porous body impregnated with Al and/or Si, and an Al₂O₃—TiC composite. A material composed of Si, SiC, and Ti is referred to as SiSiCTi, a SiC porous body impregnated with Al is referred to as AlSiC, and a SiC porous body impregnated with Si is referred to as SiSiC. When the ceramic substrate 20 is an alumina substrate, a composite used in the cooling substrate 30 is preferably AlSiC or SiSiCTi. The linear thermal expansion coefficients of alumina, AlSiC, and SiSiCTi at 40° C. to 570° C. are 7.7 × 10⁻⁶/K, 7.5 × 10⁻⁶/K, and 7.8 × 10⁻⁶/K, respectively. The cooling substrate 30 is connected to a RF power supply 62 by a feed terminal 64 therebetween. The cooling substrate 30 and the RF power supply 62 are provided with a high-pass filter (HPF) 63 therebetween. The cooling substrate 30 has, on the lower side thereof, a flange portion 34 configured to clamp the wafer placement table 10 to the installation plate 96.

As illustrated in FIG. 3, a thickness t1 of a lower part of the cooling substrate 30 below the cooling medium passage 32 is greater than or equal to 13 mm, or greater than or equal to 43% of an overall thickness B of the cooling substrate 30. The thickness t1 is preferably greater than or equal to 15 mm, or greater than or equal to 49% of the thickness B. A thickness t2 of an upper part of the cooling substrate 30 above the cooling medium passage 32 is preferably less than or equal to 5 mm, and more preferably less than or equal to 3 mm. For workability, the thickness t2 is preferably greater than or equal to 1 mm. A width w of the flange portion 34 is preferably greater than or equal to 3 mm, and more preferably greater than or equal to 10 mm. An outside diameter C of the flange portion 34 is preferably greater than or equal to 101.8% of an outside diameter A of the ceramic substrate 20, and more preferably greater than or equal to 106% of the outside diameter A.

The metal joining layer 40 joins the lower surface of the ceramic substrate 20 to the upper surface of the cooling substrate 30. The metal joining layer 40 may be, for example, a solder layer or a brazing metal layer. The metal joining layer 40 is formed, for example, by thermal compression bonding (TCB). The TCB is a known method in which a metal joining material is placed between two components to be joined, which are then pressure-bonded while being heated to a temperature lower than or equal to the solidus temperature of the metal joining material.

The side surface of the outer peripheral part 24 of the ceramic base 20, the outer periphery of the metal bonding layer 40, and the side surface of the cooling base 30 are coated with an electrically insulating film 42. Examples of the electrically insulating film 42 include a sprayed film made of alumina, yttria, or the like.

The thus configured wafer placement table 10 is attached to the mounting plate 96 inside the chamber 94 by using a clamp member 70. The clamp member 70 is an annular member with a substantially inverted L-shaped cross section and has an inner peripheral step surface 70a. The wafer placement table 10 and the mounting plate 96 are united by the clamp member 70. In a state where the inner peripheral step surface 70a of the clamp member 70 is placed on the flange 34 of the cooling base 30 of the wafer placement table 10, bolts 72 are inserted from the top surface of the clamp member 70 and screwed to threaded holes provided on the top surface of the mounting plate 96. The bolts 72 are inserted at multiple locations (for example, eight locations or 12 locations) provided at equal intervals along the circumferential direction of the clamp member 70. The clamp member 70 and the bolts 72 may be made of an electrically insulating material or may be made of an electrically conductive material (metal or the like).

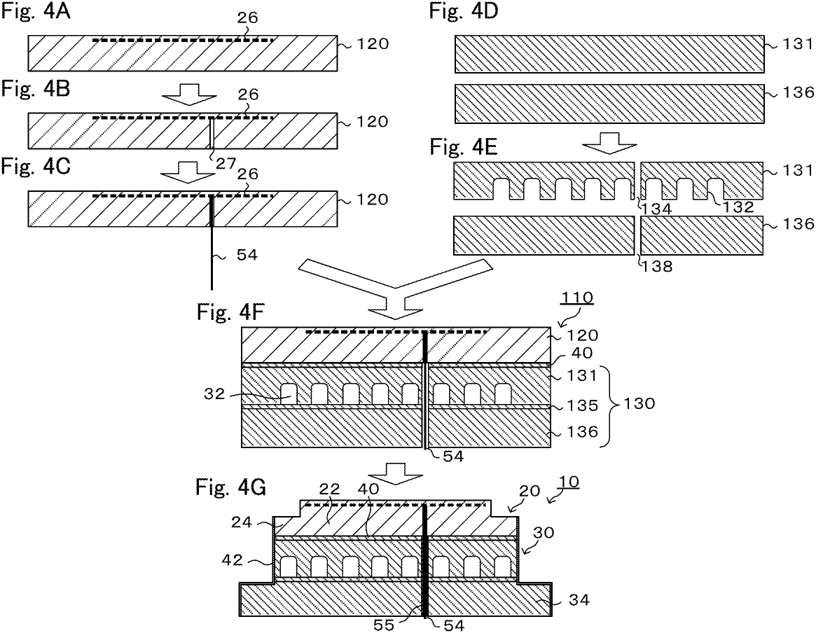

An example of manufacture of the wafer placement table 10 will now be described with reference to FIGS. 4A to 4G. FIGS. 4A to 4G illustrate a processes of manufacturing the wafer placement table 10. First, a disc-shaped sintered ceramic body 120, which is to be formed into the ceramic substrate 20, is prepared by hot-press firing of a ceramic powder molded body (FIG. 4A). The sintered ceramic body 120 contains the wafer attracting electrode 26 therein. Next, a hole 27 is formed, which extends from the lower surface of the sintered ceramic body 120 to the wafer attracting electrode 26 (FIG. 4B). The feed terminal 54 is inserted into the hole 27 and joined to the wafer attracting electrode 26 (FIG. 4C).

At the same time, two disc members 131 and 136 are prepared (FIG. 4D). A groove 132, which eventually serves as the cooling medium passage 32, is formed in the lower surface of the upper disc member 131, and through holes 134 and 138 vertically penetrating the disc members 131 and 136, respectively, are formed (FIG. 4E). The disc members 131 and 136 are made of a metal-ceramic composite. When the sintered ceramic body 120 is made of alumina, the disc members 131 and 136 are preferably made of SiSiCTi or AlSiC. This is because the thermal expansion coefficient of alumina is substantially the same as the thermal expansion coefficients of SiSiCTi and AlSiC.

For example, a SiSiCTi disc member can be made in the following manner. First, a powder mixture is prepared, which contains 39% to 51% by mass of silicon carbide raw material particles having an average particle size of greater than or equal to 10 µm and less than or equal to 25 µm and also contains one or more raw materials selected to include Ti and Si. A mass ratio of Si and Ti derived from raw materials other than silicon carbide, Si/(Si+Ti), is 0.26 to 0.54. As the raw materials, for example, silicon carbide, metallic Si, and metallic Ti can be used. In this case, the powder mixture preferably contains 39% to 51% by mass of silicon carbide, 16% to 24% by mass of metallic Si, and 26% to 43% by mass of metallic Ti. The resulting powder mixture is subjected to uniaxial pressing to form a disc-shaped molded body. Then, the molded body is hot-press sintered at 1370° C. to 1460° C. under inert atmosphere to produce a SiSiCTi disc member.

Next, a layer of metal joining material is placed between the lower surface of the upper disc member 131 and the upper surface of the lower disc member 136, and another layer of metal joining material is placed on the upper surface of the upper disc member 131. Each of the layers of metal joining material is provided with a through hole communicating with the through holes 134 and 138. The feed terminal 54 in the sintered ceramic body 120 is inserted into the through holes 134 and 138 in the disc members 131 and 136, and the sintered ceramic body 120 is placed on the layer of metal joining material on the upper surface of the upper disc member 131. The lower disc member 136, a layer of metal joining material, the upper disc member 131, another metal joining material, and the sintered ceramic body 120 are thus stacked in this order from the bottom to form a layered body. Applying heat and pressure at the same time to the layered body (by means of TCB) produces a joined body 110 (FIG. 4F). The joined body 110 includes a block 130, which is to be formed into the cooling substrate 30, and the sintered ceramic body 120 joined to the upper surface of the block 130, with a metal joining layer 40 therebetween. The block 130 includes the upper disc member 131 and the lower disc member 136 that are joined together, with a metal joining layer 135 therebetween. The block 130 has the cooling medium passage 32 therein.

The TCB described above is performed, for example, in the following manner. That is, after pressure-bonding of the layered body at a temperature lower than or equal to the solidus temperature of the metal joining material (e.g., at a temperature higher than or equal to a temperature obtained by subtracting 20° C. from the solidus temperature and lower than or equal to the solidus temperature), the layered body is left to reach room temperature. The metal joining material is thus formed into a metal joining layer. Examples of the metal joining material include an Al-Mg joining material and an Al—Si—Mg joining material. For example, when TCB is performed using an Al—Si—Mg joining material (containing 88.5% by weight of Al, 10% by weight of Mg, and 1.5% by weight of Si, and having a solidus temperature of about 560° C.), the layered body is subjected to a pressure of 0.5 kg/mm² to 2.0 kg/mm² for several hours while being heated to 540° C. to 560° C. under vacuum atmosphere. It is preferable to use a metal joining material that is around 100 µm thick.

Next, an outer region of the sintered ceramic body 120 is cut to form a step, so that the ceramic substrate 20 including the central portion 22 and the outer portion 24 is obtained. Also, an outer region of the block 130 is cut to form a step, so that the cooling substrate 30 including the flange portion 34 is obtained. Next, the insulating pipe 55 for insertion of the feed terminal 54 is placed in the through holes 134 and 138 and the holes in the layers of metal joining material. Additionally, the insulating film 42 is formed by thermally spraying, with ceramic powder, the side face of the outer portion 24 of the ceramic substrate 20, the perimeter of the metal joining layer 40, and the side face of the cooling substrate 30 (FIG. 4G). The wafer placement table 10 is thus produced.

The cooling base 30 of FIG. 1 has been described as a single-piece product; however, as shown in FIG. 4G, the cooling base 30 may be configured such that two members are bonded by a metal bonding layer or may be configured such that three or more members are bonded by metal bonding layers.

Next, an example of the use of the wafer placement table 10 will be described with reference to FIG. 1. The wafer placement table 10 is fixed to the mounting plate 96 in the chamber 94 by the clamp member 70 as described above. A shower head 98 that discharges process gas from a large number of gas injection holes into the chamber 94 is disposed on the ceiling surface of the chamber 94.

A focus ring 78 is placed on the FR placement surface 24a of the wafer placement table 10, and a disk-shaped wafer W is placed on the wafer placement surface 22a. The focus ring 78 has a step along the inner periphery of an upper end part so as not to interfere with the wafer W. In this state, the wafer W is attracted to the wafer placement surface 22a by applying a direct current voltage of the wafer attraction direct current power supply 52 to the wafer attraction electrode 26. Then, the inside of the chamber 94 is set to a predetermined vacuum atmosphere (or reduced-pressure atmosphere), and an RF voltage from the RF power supply 62 is applied to the cooling base 30 while process gas is being supplied from the shower head 98. As a result, plasma is generated between the wafer W and the shower head 98. Then, the wafer W is subjected to CVD deposition or etching by using the plasma. As the wafer W is subjected to a plasma process, the focus ring 78 abrades; however, the focus ring 78 is thicker than the wafer W, replacement of the focus ring 78 is performed after processing a plurality of wafers W.

The wafer W needs to be efficiently cooled down when treated with high-power plasma. In the wafer placement table 10, the metal joining layer 40 with high thermal conductivity, not a resin layer with low thermal conductivity, is used as a joining layer between the ceramic substrate 20 and the cooling substrate 30. This allows the wafer placement table 10 to have a high capability (or heat removing capability) of drawing heat from the wafer W. A difference in thermal expansion between the ceramic substrate 20 and the cooling substrate 30 is small and unlikely to cause a problem even when the metal joining layer 40 does not have high stress relaxation properties. Additionally, in the present embodiment, the position of the cooling medium passage 32 in the cooling substrate 30 made of a metal-ceramic composite is appropriately determined, so that the occurrence of stress in the upper part of the cooling substrate 30 above the cooling medium passage 32 is suppressed.

In the wafer placement table 10 described above, the thickness t1 of the lower part of the cooling substrate 30 below the cooling medium passage 32 is greater than or equal to 13 mm, or greater than or equal to 43% of the overall thickness B of the cooling substrate 30. Accordingly, the thickness t2 of the upper part of the cooling substrate 30 above the cooling medium passage 32 is relatively small. In the upper part of the cooling substrate 30 above the cooling medium passage 32, therefore, it is less likely that a significant temperature difference in the vertical direction will develop and lead to the occurrence of stress. The upper part of the cooling substrate 30 above the cooling medium passage 32 can thus be prevented from being damaged by the stress. Also, the stiffness of the lower part of the cooling substrate 30 below the cooling medium passage 32 is improved.

The thickness t1 of the lower part of the cooling substrate 30 below the cooling medium passage 32 is preferably greater than or equal to 15 mm, or greater than or equal to 49% of the overall thickness B of the cooling substrate 30. This further reduces the thickness t2 of the upper part of the cooling substrate 30 above the cooling medium passage 32 in relative terms, and makes it easier to prevent the upper part of the cooling substrate 30 above the cooling medium passage 32 from being damaged by stress.

The thickness t2 of the upper part of the cooling substrate 30 above the cooling medium passage 32 is preferably less than or equal to 5 mm. This can enhance the effect described above. If the thickness t2 is less than or equal to 3 mm, the effect described above can be further enhanced.

It is preferable that the width w of the flange portion 34 be greater than or equal to 3 mm, or that the outside diameter C of the flange portion 34 be greater than or equal to 101.8% of the outside diameter A of the ceramic substrate 20. This can reduce the risk of warpage of the wafer placement table 10 caused by clamping the flange portion 34 of the wafer placement table 10 with a clamp member 70, reduce the risk of damage to the product, and improve thermal uniformity. It is more preferable that the width w of the flange portion 34 be greater than or equal to 10 mm, or that the outside diameter C of the flange portion 34 be greater than or equal to 106% of the outside diameter A of the ceramic substrate 20. This can further reduce the risk of warpage, further reduce the risk of damage to the product, and further improve thermal uniformity.

The upper corners 32a of the cooling medium passage 32 are rounded in cross section. This can prevent the occurrence of cracks originating from the corners 32a.

When the ceramic substrate 20 is an alumina substrate, the metal-ceramic composite is preferably AlSiC or SiSiCTi. This is because the absolute difference in linear thermal expansion coefficient, at 40° C. to 570° C., between alumina and AlSiC or SiSiCTi is small.

The present invention is by no means limited to the embodiments described above, and can be implemented in various ways within the technical scope of the present invention.

In the embodiments described above, for example, the wafer placement table 10 may have holes that extend therethrough from the lower surface of the cooling substrate 30 to reach the wafer placement surface 22a. Examples of such holes include gas supply holes for supplying a heat-transfer gas (e.g., He gas) to the back surface of the wafer W, and lift pin holes for insertion of lift pins with which the wafer W is lifted and lowered with respect to the wafer placement surface 22a. The heat-transfer gas is supplied to spaces formed by unillustrated many small protrusions (which support the wafer W) provided on the wafer mounting surface 22a and the wafer W. For example, for supporting the wafer W with three lift pins, lift pin holes are provided at three points.

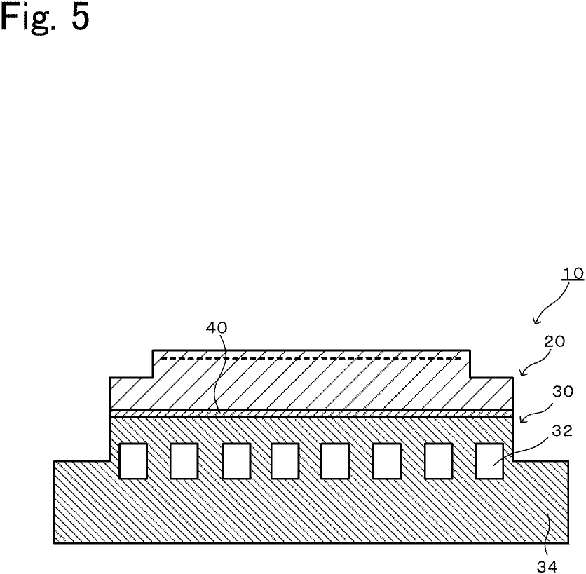

In the wafer placement table 10 of the embodiments described above, the height of the flange portion 34 of the cooling substrate 30 is lower than the bottom surface of the cooling medium passage 32. As illustrated in FIG. 5, however, the height of the flange portion 34 of the cooling substrate 30 may be higher than the bottom surface of the cooling medium passage 32. This improves stiffness of the cooling substrate 30 and makes it easier to prevent warpage of the wafer placement table 10 clamped to the installation plate 96 with the clamp member 70.

Although the central portion 22 of the ceramic substrate 20 contains the wafer attracting electrode 26 in the embodiments described above, the central portion 22 of the ceramic substrate 20 may contain a RF electrode for plasma generation instead of, or in addition to, the wafer attracting electrode 26. In this case, the RF electrode is connected to a high-frequency power source. The outer portion 24 of the ceramic substrate 20 may contain a focus ring (FR) attracting electrode. In this case, a direct-current power supply is connected to the FR attracting electrode.

In the embodiments described above, the sintered ceramic body 120 illustrated in FIG. 4A is made by hot-press firing of a ceramic powder molded body. The molded body may be made by stacking a plurality of tape-cast layers, by a mold casting method, or by compacting ceramic powder.

### EXAMPLES

Examples of the present invention will now be described. The examples described below are by no means intended to limit the present invention.

### [Experimental Examples 1 to 5]

As Experimental Examples 1 to 5, the wafer placement tables 10 of different dimensions were analyzed with the finite element method (FEM). The following conditions are common to Experimental Examples 1 to 5. The ceramic substrate 20 is an alumina substrate that is 296 [mm] in the diameter of the central portion 22, 335.8 [mm] in overall outside diameter A, and 4.6 [mm] in overall thickness. The cooling substrate 30 is made of SiSiCTi and is 30.12 [mm] in overall thickness B and 7.6 [mm] in length from the upper surface of the cooling substrate 30 to the upper surface of the flange portion 34. A cross section of the cooling medium passage 32 is 12.12 [mm] in vertical length (or height), 8 [mm] in horizontal length (or width), and 1 [mm] in the radius of curvature of the upper corners 32a. The metal joining layer 40 is made of an Al-containing joining material and is 0.12 [mm] in thickness.

For the thickness t1 of the lower part of the cooling substrate 30 below the cooling medium passage 32, the thickness t2 of the upper part of the cooling substrate 30 above the cooling medium passage 32, and the width w of the flange portion 34, values shown in Table 1 were used in each Experimental Example. Table 1 also shows the ratio of the thickness t1 to the overall thickness B of the cooling substrate 30, t1/B [%], the ratio of the width w of the flange portion 34 to the outside diameter A of the ceramic substrate 20, w/A [%], and the ratio of the outside diameter C of the flange portion 34 to the outside diameter A of the ceramic substrate 20, C/A [%].

For Experimental Examples 1 to 5, the maximum stress [MPa] in a cross section of the cooling medium passage 32 was determined by FEM under conditions where heat input to the wafer placement surface 22a was 210 [kW/m²], the temperature of a cooling medium passing through the cooling medium passage 32 was 55 [°C], the target temperature of the wafer placement surface 22a was 100 [°C], and pressure load applied by the clamp member 70 to the flange portion 34 was 90000 [N]. Evaluation was made on the basis of the maximum stress [MPa] determined. The result is shown in Table 1.

TABLE 1

| Experimental Examples | Metal-ceramic composite | Parameter regarding to the cooling medium passage | | | Parameter regarding to the flange | | | Temperature of the wafer placement surface [°C] | Temperature of the upper surface of the cooling substrate [°C] | Vertical temperature difference in the upper part of the cooling medium passage [°C] | Results | |
|---|---|---|---|---|---|---|---|---|---|---|---|---|
| | | t2 [mm] | t1 [mm] | t1/B [%] | w [mm] | w/A [%] | C/A [%] | | | | Maximum stress [Mpa] | Evaluation |
| 1 | SiSiCTi | 10 | 8 | 26.6 | 3 | 0.9 | 101.8 | 112.4 | 80.4 | 25.5 | 82 | Poor |
| 2 | SiSiCTi | 5 | 13 | 43.2 | 3 | 0.9 | 101.8 | 103.5 | 72.0 | 17.0 | 73 | Good |
| 3 | SiSiCTi | 3 | 15 | 49.8 | 3 | 0.9 | 101.8 | 100.4 | 69.3 | 14.3 | 66 | Good |
| 4 | SiSiCTi | 5 | 13 | 43.2 | 10 | 3.0 | 106.0 | - | - | - | 66 | Good |
| 5 | SiSiCTi | 3 | 15 | 49.8 | 10 | 3.0 | 106.0 | - | - | - | 60 | Excellent |
| 6 | AISiC | 10 | 8 | 26.6 | 3 | 0.9 | 101.8 | 103.1 | 71.0 | 15.5 | 84 | Poor |
| 7 | AISiC | 3 | 15 | 49.8 | 10 | 3.0 | 106.0 | 95.7 | 64.2 | 8.7 | 24 | Excellent |

※t1=Thickness of the lower part of the cooling substrate below the cooling medium passage [mm], t2=Thickness of the upper part of the cooling substrate above the cooling medium passage [mm], w=Flange Width [mm]
A=Outermost diameter of the seramic substrate [mm], B=Overall thickness of the cooling substrate [mm], C=Outermost diameter of the cooling substrate [mm]

Experimental Examples 1 to 3 are the same in the width w (= 3 [mm]) of the flange portion 34, but are different in thickness t1. The result in Table 1 shows that the maximum stress in Experimental Examples 2 and 3 where t1 was greater than or equal to 13 [mm] (t1/B was greater than or equal to 43.2 [%]) was smaller, by as much as greater than or equal to 10%, than the maximum stress in Experimental Example 1 where t1 was 8 [mm] (t1/B was 26.6 [%]). Table 1 also shows that the maximum stress in Experimental Example 3 where t1 was 15 [mm] was smaller than the maximum stress in Experimental Example 2 where t1 was 13 [mm]. When the wafer placement tables 10 for Experimental Examples 1 and 2 were actually made and used under the conditions described above, cracks were observed in Experimental Example 1, whereas no cracks were observed in Experimental Example 2.

The temperature of the wafer placement surface of the ceramic substrate 20, the temperature of the upper surface of the cooling substrate 30, and the vertical temperature difference in the upper part of the cooling substrate 30 above the cooling medium passage 32 were as shown in Table 1. The temperature of the upper surface of the cooling substrate 30 is the temperature at the joint interface of the cooling substrate 30 and the metal joining layer 40. The vertical temperature difference in the upper part of the cooling substrate 30 above the cooling medium passage 32 is a difference between the temperature at the joint interface of the cooling substrate 30 and the metal joining layer 40 and the temperature of the ceiling surface of the cooling medium passage 32 in the cooling substrate 30. The results described above show that as t1 increases (or in other words, as t2 decreases), the vertical temperature difference in the upper part of the cooling substrate 30 above the cooling medium passage 32 decreases. As described above, the greater the value of t1, the smaller the maximum stress. A possible contributing factor to this would be that as t1 increases, the vertical temperature difference in the upper part of the cooling substrate 30 above the cooling medium passage 32 decreases and becomes less likely to cause stress in this upper part of the cooling substrate 30.

Experimental Examples 2 and 4 are the same in thickness t1 (= 13 mm), but are different in the width w of the flange portion 34. The result in Table 1 shows that the maximum stress in Experimental Example 4 where the width w of the flange portion 34 was 10 [mm] (w/A was 3.0 [%], C/A was 106.0 [%]) was smaller than the maximum stress in Experimental Example 2 where the width w of the flange portion 34 was 3 [mm] (w/A was 0.9 [%], C/A was 101.8 [%] ).

Experimental Examples 3 and 5 are the same in thickness t1 (= 15 mm), but are different in the width w of the flange portion 34. The result in Table 1 shows that the maximum stress in Experimental Example 5 where the width w of the flange portion 34 was 10 [mm] (w/A was 3.0 [%], C/A was 106.0 [%]) was smaller than the maximum stress in Experimental Example 3 where the width w of the flange portion 34 was 3 [mm] (w/A was 0.9 [%], C/A was 101.8 [%] ) . The maximum stress in Experimental Example 5 was the smallest of those in Experimental Examples 1 to 5.

### [Experimental Examples 6 and 7]

Experimental Example 6 is the same as Experimental Example 1 except that AlSiC, instead of SiSiCTi, was used as a metal-ceramic composite to make the cooling substrate 30. Experimental Example 7 is the same as Experimental Example 5 except that AlSiC, instead of SiSiCTi, was used as a metal-ceramic composite to make the cooling substrate 30. For Experimental Examples 6 and 7, the maximum stress was determined, evaluation was made, and the temperature of the wafer placement surface of the ceramic substrate 20, the temperature of the upper surface of the cooling substrate 30, and the vertical temperature difference in the upper part of the cooling substrate 30 above the cooling medium passage 32 were determined in the same manner as in Experimental Examples 1 to 5. The result is shown in Table 1. The maximum stress in Experimental Example 7 was much smaller than that in Experimental Example 6.

As shown in Table 1, Experimental Examples 1 and 6 were evaluated as “poor”, Experimental Examples 2 to 4 were evaluated as “good”, and Experimental Examples 5 and 7 were evaluated as “excellent”. Experimental Examples 1 and 6 correspond to comparative examples, and Experimental Examples 2 to 5 and 7 correspond to examples of the present invention.

This application claims priority to Japanese Patent Application No. 2021-146681 filed on Sep. 9, 2021, the entire contents of which are incorporated herein by reference. International Application No. PCT/JP2022/025141, filed on Jun. 23, 2022, is incorporated herein by reference in its entirety.

What is claimed is:

1. A wafer placement table comprising:
a ceramic substrate having a wafer placement surface on an upper surface thereof and containing an electrode therein;
a cooling substrate made of a metal-ceramic composite and having a cooling medium passage formed therein; and
a metal joining layer configured to join a lower surface of the ceramic substrate to an upper surface of the cooling substrate,
wherein a thickness of a lower part of the cooling substrate below the cooling medium passage is greater than or equal to 13 mm, or greater than or equal to 43% of an overall thickness of the cooling substrate.

2. The wafer placement table according to claim 1, wherein the thickness of the lower part of the cooling substrate below the cooling medium passage is greater than or equal to 15 mm, or greater than or equal to 49% of the overall thickness of the cooling substrate.

3. The wafer placement table according to claim 1, wherein a thickness of an upper part of the cooling substrate above the cooling medium passage is less than or equal to 5 mm.

4. A wafer placement table comprising:
a ceramic substrate having a wafer placement surface on an upper surface thereof and containing an electrode therein;
a cooling substrate made of a metal-ceramic composite and having a cooling medium passage formed therein; and
a metal joining layer configured to join a lower surface of the ceramic substrate to an upper surface of the cooling substrate,
wherein a thickness of an upper part of the cooling substrate above the cooling medium passage is less than or equal to 5 mm.

5. The wafer placement table according to claim 3, wherein the thickness of the upper part of the cooling substrate above the cooling medium passage is less than or equal to 3 mm.

6. The wafer placement table according to claim 1, wherein the cooling substrate has, on a lower side thereof, a flange portion configured to clamp the wafer placement table; and a width of the flange portion is greater than or equal to 3 mm, or an outside diameter of the flange portion is greater than or equal to 101.8% of an outside diameter of the ceramic substrate.

7. The wafer placement table according to claim 6, wherein the width of the flange portion is greater than or equal to 10 mm, or the outside diameter of the flange portion is greater than or equal to 106% of the outside diameter of the ceramic substrate.

8. The wafer placement table according to claim 1, wherein upper corners of the cooling medium passage are rounded in cross section.

9. The wafer placement table according to claim 1, wherein an absolute difference in linear thermal expansion coefficient at 40° C. to 570° C. between the metal-ceramic composite and a ceramic material forming the ceramic substrate is less than or equal to 1 × 10⁻⁶/_{K}.

10. The wafer placement table according to claim 4, wherein the thickness of the upper part of the cooling substrate above the cooling medium passage is less than or equal to 3 mm.

11. The wafer placement table according to claim 4, wherein the cooling substrate has, on a lower side thereof, a flange portion configured to clamp the wafer placement table; and a width of the flange portion is greater than or equal to 3 mm, or an outside diameter of the flange portion is greater than or equal to 101.8% of an outside diameter of the ceramic substrate.

12. The wafer placement table according to claim 11, wherein the width of the flange portion is greater than or equal to 10 mm, or the outside diameter of the flange portion is greater than or equal to 106% of the outside diameter of the ceramic substrate.

13. The wafer placement table according to claim 4, wherein upper corners of the cooling medium passage are rounded in cross section.

14. The wafer placement table according to claim 4, wherein an absolute difference in linear thermal expansion coefficient at 40° C. to 570° C. between the metal-ceramic composite and a ceramic material forming the ceramic substrate is less than or equal to 1 × 10⁻⁶/K.
